(19) United States
(12) Patent Application Publication
(10) Pub. No.: US 2025/0105835 A1
(43) Pub. Date: Mar. 27, 2025

(54) Output Driving Circuit for Power Devices

(71) Applicant: Nanjing Greenchip Semiconductor Co., Ltd., Nanjing (CN)

(72) Inventors: Chi-Hao WU, Nanjing City (CN); Wen-An TSOU, Nanjing City (CN)

(21) Appl. No.: 18/384,879

(22) Filed: Oct. 29, 2023

(30) Foreign Application Priority Data
Sep. 27, 2023 (CN) 202311270298.3

(51) Int. Cl. H03K 17/10; H03K 17/687; H03K 19/0185

(52) U.S. Cl. CPC H03K 17/102; H03K 17/6871; H03K 19/018521

(57) ABSTRACT

An output driving circuit for power devices includes an output stage module comprising a high-side PMOS and a low-side NMOS power transistors, the high-side PMOS power transistor having its source connected to a power supply through a resistor electrically connected in series between the PMOS power transistor and the power supply, having its drain electrically connected to drain of the low-side NMOS power transistor, and source of the NMOS power transistor connected to ground. A first inverter electrically connected to gate of the high-side PMOS power transistor to drive the high-side PMOS power transistor, and a second inverter electrically connected to gate of the low-side NMOS power transistor to drive the low-side NMOS power transistor. A voltage control signal is input from input terminals of the first and the inverters, used to respectively control turn-on and turn-off states of the high-side PMOS power transistor and the low-side NMOS power transistor.

### CROSS-REFERENCE STATEMENT

The present application is based on, and claims priority from, China Patent Application Serial Number 202311270298.3, filed Sep. 27, 2023, the disclosure of which is hereby incorporated by reference herein in its entirety.

### TECHNICAL FIELD

The present invention relates to the technology field of driving circuit, and more particularly, an output driving circuit for power devices.

### BACKGROUND

It is well known that the switching power supply technology has been widely used in the field of power circuits. For switching circuits, power transistors, such as MOSFET, IGBT, SiC or GaN, are used as switching devices, which are widely used in power electronic systems.

Currently, a commonly used driving circuit for power transistor is depicted in FIG. 1, which includes a current mirror 101 and an output stage 103 to form a power device driving circuit, and is used to drive power transistors used as power switching devices in power circuits. Among them, the current of the last stage of the driving circuit used to drive the power switching devices is amplified from the initial current source of 50 uA to 200 mA in two stages. The shortcomings of the driving circuit shown in FIG. 1 are very obvious, because the circuit is complex and consumes a lot of power while operating it.

Since the driving circuit for power transistor is widely used in power electronic systems, it is usually integrated into a power management integrated circuit (IC) or similar power control IC in the form of an integrated circuit.

Taking MOSFET as an example, the switching signal of the power transistor is generally provided by a logic circuit or a microcontroller, and the current of its output signal is generally limited to a few milliamps. If the power transistor is directly driven by this signal, its switching speed will be very slow and the switching loss will be large. During switching, the gate capacitor will draw current quickly, which may draw too much current from the logic circuit or microcontroller, causing permanent damage to the chip. In order to avoid these situations, a gate driver is usually added between the logic circuit, the microcontroller output circuit and the power transistor.

In addition, since today's electronic devices, especially consumer electronic products, require small size and powerful functions, the integration level of electronic devices is rapidly increasing. Due to the high degree of integration of the electronic devices, the distance between electronic components in chips and printed circuit boards will be reduced, which can directly or indirectly cause electromagnetic interference (EMI) during operation of electronic devices.

Based on aforementioned concerns, the driving circuit for the power devices needs to be further optimized to reduce the switching loss of the power devices and to reduce the electromagnetic interference (EMI) while operating these devices.

### SUMMARY

In view of the shortcomings of the conventional technology, according to one aspect of the present invention, an output driving circuit for a power device is proposed, which includes a high-side PMOS power transistor and a low-side NMOS power transistor, the high-side PMOS power transistor having its source connected to a power supply through a resistor electrically connected in series between the PMOS power transistor and the power supply, the high-side PMOS power transistor having its drain electrically connected to drain of the low-side NMOS power transistor, and source of the NMOS power transistor connected to ground. A first inverter having its output terminal electrically connected to gate of the high-side PMOS power transistor to drive the high-side PMOS power transistor, and a second inverter having its output terminal electrically connected to gate of the low-side NMOS power transistor to drive the low-side NMOS power transistor. A voltage control signal is input from input terminals of the first inverter and the second inverter, used to respectively control turn-on and turn-off states of the high-side PMOS power transistor and the low-side NMOS power transistor.

In one preferred embodiment, the voltage control signal is PWM signal.

In one preferred embodiment, both the first inverter and the second inverter are constructed with push-pull structure, where the first inverter includes a first PMOS transistor connected to a first NMOS transistor, source of the first PMOS connected to the power supply, drain of the first PMOS transistor connected to drain of the first NMOS transistor, and source of the first NMOS transistor connected to ground, and where the second inverter includes a second PMOS transistor connected to a second NMOS transistor, source of the second PMOS connected to the power supply, drain of the second PMOS transistor connected to drain of the second NMOS transistor, and source of the second NMOS transistor connected to ground.

In another aspect of the present invention, an output driving circuit for power devices is proposed, which includes a plurality of high-side driving arms connected in parallel, each high-side driving arm having a high-side PMOS power transistor with its source connected in series to a power supply through a resistor connected in series between the high-side PMOS power transistor and the power source, a low-side driving arm, connected in series to the plurality of high-side driving arms, the low-side driving arm containing a low-side NMOS power transistor with its drain connected to common drain of the plurality of high-side driving arms and its source connected to ground, and an output capacitor connected between the drain of the low-side NMOS power transistor and ground been segmentally driven through sequentially inputting timing control signals to drive each of the high-side driving arms and adjusting resistance value of the resistor connected between the power supply and the high-side PMOS power transistor of each of the high-side driving arms.

In one preferred embodiment, each of the timing control signals is PWM signals.

In one preferred embodiment, the gate of the high-side PMOS power transistor of each of the high-side driving arms is electrically connected to an inverter for individually inputting control signal to drive the PMOS power transistor on and off. The control signal is inverted with the timing control signal. The inverter is constructed with a push-pull structure.

In one preferred embodiment, the inverter includes a PMOS transistor connected to an NMOS transistor, source of the PMOS transistor connected to the power supply, drain of the PMOS transistor connected to drain of the NMOS transistor, source of the NMOS transistor is grounded, and both gate of the PMOS transistor and gate of the NMOS transistor connected together as an input terminal of the control signal.

### BRIEF DESCRIPTION OF THE DRAWINGS

The components, characteristics and advantages of the present invention may be understood by the detailed descriptions of the preferred embodiments outlined in the specification and the drawings attached:

FIG. 1 shows a schematic diagram of a driving circuit for a power transistor according to the prior art.

FIG. 2 depicts a schematic diagram of a driving circuit for a power transistor according to one preferred embodiment of the present invention.

FIG. 3(A) depicts a schematic diagram of a driving circuit for a power transistor according to another embodiment of the present invention.

FIG. 3(B) illustrates input timing signals and corresponding output voltages of the driving circuit proposed in FIG. 3(A).

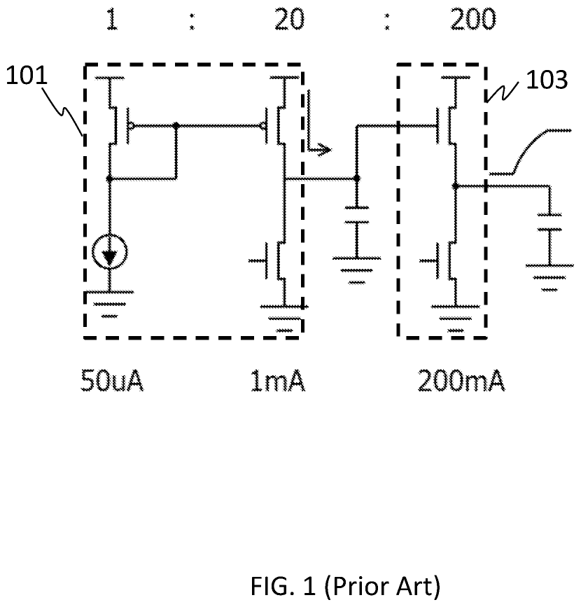

### DETAILED DESCRIPTION

Some preferred embodiments of the present invention will now be described in greater detail. However, it should be recognized that the preferred embodiments of the present invention are provided for illustration rather than limiting the present invention. In addition, the present invention can be practiced in a wide range of other embodiments besides those explicitly described, and the scope of the present invention is not expressly limited except as specified in the accompanying claims.

The purpose of the present invention is to provide a driving circuit that can be used to drive power devices, such as a power transistors.

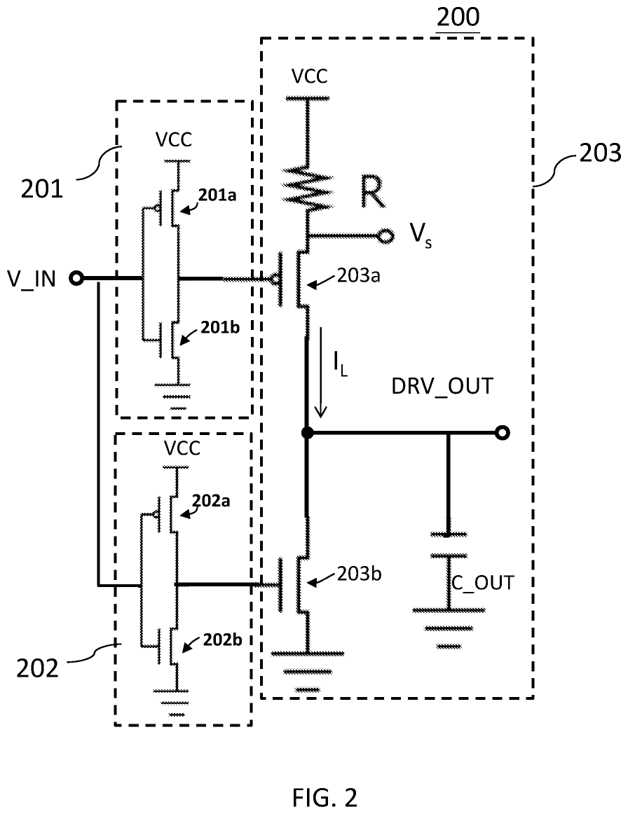

To achieve the above purpose, please refer to FIG. 2, according to one aspect of the present invention, a driving circuit 200 for driving power devices is proposed. The architecture of the driving circuit 200 includes a first inverter 201, which is composed of a first PMOS transistor 201a connected to a first NMOS transistor 201b, a second inverter 202, which is composed of a second PMOS transistor 202a connected to a second NMOS transistor 202b, and an output stage module 203. Both the first inverter 201 and the second inverter 202 are constructed with push-pull circuit structures. The first inverter 201 includes a first PMOS transistor 201a connected to a first NMOS transistor 201b, where the source of the first PMOS transistor 201a is connected to a power supply VCC, the drain of the first PMOS transistor 201a is connected to the drain of the first NMOS transistor 201b, the source of the first NMOS transistor 201b is connected to ground, and the gates of both the first PMOS transistor 201a and the first NMOS transistor 201b are connected together as an input terminal for inputting the control signal V_IN. Similarly, the second inverter 202 includes a second PMOS transistor 202a connected to a second NMOS transistor 202b, where the source of the second PMOS transistor 202a is connected to the power supply VCC, the drain of the second PMOS transistor 202a is connected to the drain of the second NMOS transistor 202b, the source of the second NMOS transistor 202b is connected to ground, and the gates of both the second PMOS transistor 201a and the second NMOS transistor 201b are connected together as an input terminal for inputting the control signal V_IN. The first inverter 201 serves as a driver for driving the high-side PMOS power transistor 203a of the output stage module 203, and its output terminal is connected to the gate of the high-side PMOS power transistor 203a. The second inverter 202 serves as a driver for driving the low-side NMOS power transistor 203b of the output stage 203a, and its output terminal is connected to the gate of the low-side NMOS power transistor 203b.

According to some embodiments of the present invention, the source of the high-side PMOS power transistor 203a is connected to the power supply VCC through a resistor R, the drain of the low-side NMOS power transistor 203b is connected to the drain of the high-side PMOS power transistor 203a, and the source of the NMOS power transistor 203b is grounded. An output capacitor C_OUT has a first end connected to the common drain terminal of the high-side PMOS power transistor 203a and the low-side NMOS power transistor 203b, serving as the output terminal (DRV_OUT) of the driving circuit 200, and the other end (second end) is connected to ground.

In some embodiments, the driving circuit 200 further includes an input terminal for switching control signal V_IN that is transmitted to required positions of the driving circuit as a basis for timing control while operating the driving circuit 200. The switching control signal V_IN is a PWM control signal, both the high-side PMOS power transistor 203a and the low-side NMOS power transistor 203b can be controlled to be turned on (ON) or turned off (OFF) through different circuit function selections and paths, the details of which will be described in the following paragraphs.

In some embodiments, the high-side PMOS power transistor 203a is controlled by the first inverter 201. When the control signal V_IN input from the input terminal of the first inverter 201 is at its high level, the first PMOS transistor 201a is turned off and the first NMOS transistor 201b is turned on, and the first inverter 201 outputs a low-level control signal, causing the high-side PMOS power transistor 203a to be turned on. At this moment, the control signal V_IN input from the input terminal of the second inverter 202 is also at a high level, the second PMOS transistor 202a is turned off and the second NMOS transistor 202b is turned on, and the second inverter 202 outputs a low-level control signal, so that the low-side NMOS power transistor 203b is turned off. The power supply VCC charges the output capacitor C_OUT through the resistor R and the high-side PMOS power transistor 203a, and outputs the driving signal V_DRV_OUT.

According to an embodiment of the present invention, the current charging the output capacitor C_OUT is

$${I}_{L} = \frac{VCC - Vs}{R} ,$$

where V_{S} is the source voltage of the high-side PMOS power transistor 203a.

Similarly, when the control signal V_IN input from the input terminal of the first inverter 201 is at its low level, the first PMOS transistor 201a is turned on and the first NMOS transistor 201b is turned off, and the first inverter 201 outputs a high-level control signal, so that the high side PMOS power transistor 203a is turned off. At this moment, the control signal V_IN input from the input terminal of the second inverter 202 is also at its low level, the second PMOS transistor 202a is turned on and the second NMOS transistor 202b is turned off, and a high level control signal is output from the second inverter 202, causing the low-side NMOS power transistor 203b to be turned on. The capacitor C_OUT discharges to ground through the discharging path from the low-side NMOS power transistor 203b to ground.

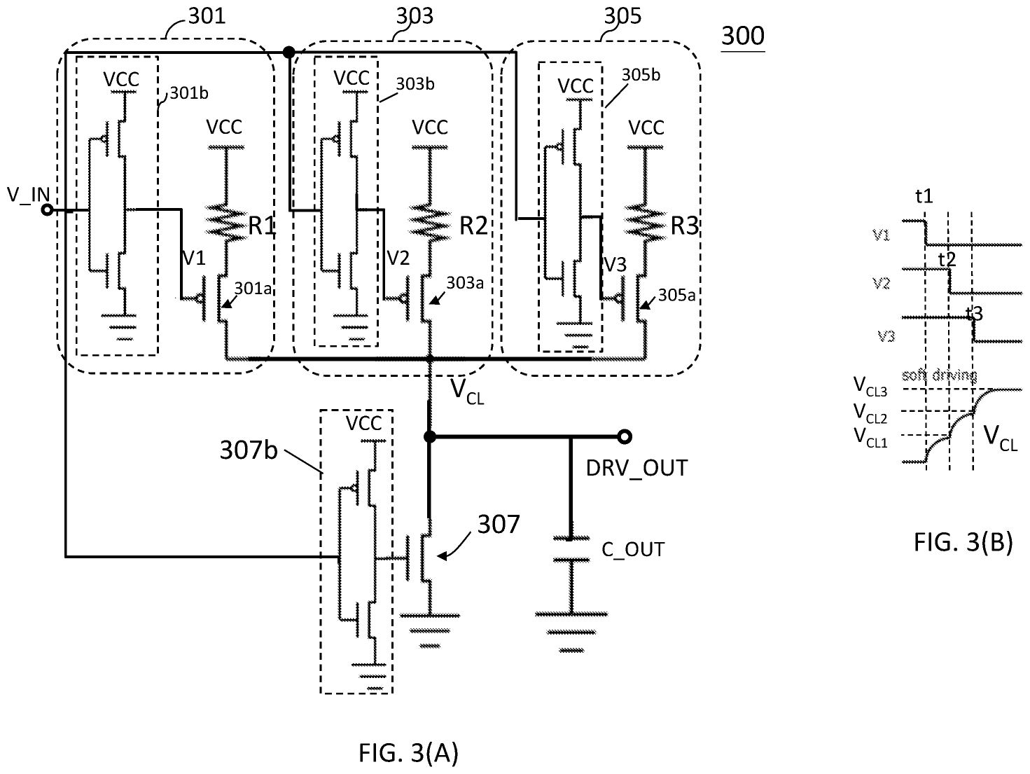

In order to reduce the electromagnetic interference (EMI) generated by the electronic devices during operation of the driving circuit, it is necessary to avoid rapid switching operations being performed on transistors of the output stage to form instantaneous voltages, which can produce electromagnetic interference signals to a power supply system that the driving circuit is working with. Therefore, a novel driving circuit applied to the power supply system is proposed. According to another aspect of the present invention, as shown in FIG. 3(A), a driving circuit 300 for driving power devices, which includes a plurality of linear driving architectures similar to that has been shown in FIG. 2. Specifically, the present invention proposes to utilize a plurality of high-side driving arms, each is at least consisted of a high-side PMOS power transistor, connected in parallel, and then connect in serial to a low-side driving arm, formed by NMOS power transistor, to form an output driving circuit for power devices. The driving circuit can achieve the purpose of segmented driving of the output capacitor C_OUT by arranging timing control signals and regulating charging power, where the regulation of charging power for each high-side driving arm can be accomplished by appropriately selecting a resistor R connected between a high-side PMOS power transistor and the power supply VCC.

The circuit architecture of the driving circuit 300, referring to FIG. 3(A), includes a first high-side driving arm 301, a second high-side driving arm 303, a third high-side driving arm 305 and a low-side driving arm 307, where the first high-side driving arm 301, the second high-side driving arm 303 and the third high side driving arm 305 are connected in parallel to form an assembled high-side driving arm, and the low-side driving arm 307 is connected in series with the assembled high-side driving arm. Similar to the driving circuit 200 shown in FIG. 2, the first high-side driving arm 301 includes a first high-side PMOS power transistor 301a having its source connected to the power supply VCC through a first resistor R1. A first inverter 301b having its output terminal connected to the gate of the first high-side PMOS power transistor 301a is used to input a first timing signal V1 to control the ON/OFF state of the first high-side PMOS power transistor 301a. Similar to FIG. 2, when the first timing signal V1 is at high level (low level), the first high-side PMOS power transistor 301a is turned off (turned on), and the high and low levels of the first timing signal V1 are inverted with the input control signal V_IN. Similarly, the second high-side driving arm 303 includes a second high-side PMOS power transistor 303a having its source connected to the power supply VCC through a second resistor R2. A second inverter 303b having its output terminal connected to the gate of the second high-side PMOS power transistor 303a is used to input a second timing signal V2 to control the ON/OFF state of the second high-side PMOS power transistor 303a. When the second timing signal V2 is at high level (low level), the second high-side PMOS power transistor 303a is turned off (turned on), and the high and low levels of the second timing signal V2 are inverted with the input control signal V_IN. Similarly, the third high-side driving arm 305 includes a third high-side PMOS power transistor 305a having its source connected to the power supply VCC through a third resistor R3. A third inverter 305b having its output terminal connected to the gate of the third high-side PMOS power transistor 305a is used to input a third timing signal V3 to control the ON/OFF states of the third high-side PMOS power transistor 305a. When the third timing signal V3 is at high level (low level), the third high-side PMOS power transistor 305a is turned off (turned on), and the high and low levels of the third timing signal V3 are inverted with the input control signal V_IN.

Please refer to FIGS. 3(A)-3(B), when the timing signals V1, V2 and V3 respectively convert from high level to low level in time periods t1, t2 and t3, the first high-side PMOS power transistor 301a of the first high-side driving arm 301, the second high-side PMOS power transistor 303a of the second driving arm 303, and the third high-side PMOS power transistor of the third high-side driving arm 305a, are turned on sequentially, while the low-side NMOS power transistor 307 is turned off. Therefore, during the time period between t1 and t2, the power supply VCC starts to charge the output capacitor C_OUT up to a voltage V_CL1 through a first charging path composed of the first resistor R1 and the first high-side PMOS power transistor 301a. During the time period between t2 and t3, the power supply VCC starts to charge the output capacitor C_OUT up to a voltage V_CL2 through an added second charging path composed of the second resistor R2 and the second high-side PMOS power transistor 303a. During the time period between t3 and beyond, the power supply VCC starts to charge the capacitor C_OUT through an added third charging path composed of the third resistor R3 and the third high-side PMOS power transistor 305a, if the above charging paths are continued to be turned on, the capacitor C_OUT can be continuously charged to the target voltage value VCL3.

According to some embodiments of the present invention, the first inverter 301b, the second inverter 303b and the third inverter 305b are all push-pull structures, where each inverter includes a PMOS transistor connected to a NMOS transistor, the source of the PMOS transistor is connected to the power supply VCC, the drain of the PMOS transistor is connected to the drain of the NMOS transistor, the source of the NMOS transistor is connected to ground, and the gates of these two transistors are connected together to act as the signal input terminal for inputting the control signal V_IN.

According to some embodiments of the present invention, when the timing signals V1, V2 and V3 are respectively converted from high level to low level in the time periods t1, t2 and t3, the low-side NMOS power transistor 307 is turned off; otherwise, the low-side NMOS power transistor 307 is turned on.

According to some embodiments of the present invention, similar to the circuit architecture shown in FIG. 2, the low-side NMOS power transistor 307 is driven by the output signal of a fourth inverter 307b to control ON/OFF states of the low-side NMOS power transistor 307, that is, when the control signal V_IN fed from the input terminal of the fourth inverter 307b is at high level, it outputs a low-level control signal to turn off the low-side NMOS power transistor 307, which has its gate electrically connected to the signal output terminal of the fourth inverter 307b.

Therefore, through clarifying the operation of the above-mentioned circuit structure, the driving circuit 300 mentioned in FIG. 3(A) proposed by the present invention can achieve the effect of soft driving through segmental driving and can avoid the issue of electromagnetic interference signals resulting form the rapid switching operation of the power transistors in the output stage.

While various embodiments of the present invention have been described above, it should be understood that they have been presented by a way of example and not limitation. Numerous modifications and variations within the scope of the invention are possible. The present invention should only be defined in accordance with the following claims and their equivalents.

What is claimed is:

1. An output driving circuit for power devices, comprising:
an output stage module including a high-side PMOS power transistor and a low-side NMOS power transistor, said high-side PMOS power transistor having its source connected to a power supply through a resistor electrically connected in series between said PMOS power transistor and said power supply, said high-side PMOS power transistor having its drain electrically connected to drain of said low-side NMOS power transistor, and source of said NMOS power transistor connected to ground;
a first inverter having its output terminal electrically connected to gate of said high-side PMOS power transistor to drive said high-side PMOS power transistor; and
a second inverter having its output terminal electrically connected to gate of said low-side NMOS power transistor to drive said low-side NMOS power transistor;
wherein a voltage control signal is input from input terminals of said first inverter and said second inverter, used to respectively control turn-on and turn-off states of said high-side PMOS power transistor and said low-side NMOS power transistor.

2. The output driving circuit of claim 1, wherein said voltage control signal is PWM signal.

3. The output driving circuit of claim 1, wherein both said first inverter and said second inverter are constructed with push-pull structure.

4. The output driving circuit of claim 3, wherein said first inverter includes a first PMOS transistor connected to a first NMOS transistor, source of said first PMOS connected to said power supply, drain of said first PMOS transistor connected to drain of said first NMOS transistor, and source of said first NMOS transistor connected to ground.

5. The output driving circuit of claim 3, wherein said second inverter includes a second PMOS transistor connected to a second NMOS transistor, source of said second PMOS connected to said power supply, drain of said second PMOS transistor connected to drain of said second NMOS transistor, and source of said second NMOS transistor connected to ground.

6. An output driving circuit for power devices, comprising:
a plurality of high-side driving arms connected in parallel, each high-side driving arm having a high-side PMOS power transistor with its source connected to a power supply through a resistor connected in series between said high-side PMOS power transistor and said power source;
a low-side driving arm, connected in series to said plurality of high-side driving arms, said low-side driving arm containing a low-side NMOS power transistor with its drain connected to common drain of said plurality of high-side driving arms and its source connected to ground; and
an output capacitor connected between said drain of said low-side NMOS power transistor and ground been segmentally driven through sequentially inputting timing control signals to drive each of said high-side driving arms and adjusting resistance value of said resistor connected between said power supply and said high-side PMOS power transistor of each of said high-side driving arms.

7. The output driving circuit of claim 6, wherein each of said timing control signals is PWM signals.

8. The output driving circuit of claim 7, wherein said gate of the high-side PMOS power transistor of each of the high-side driving arms is electrically connected to an inverter for individually inputting control signal to drive said PMOS power transistor on and off.

9. The output driving circuit of claim 8, wherein said control signal is inverted with said timing control signal.

10. The output driving circuit of claim 8, wherein said inverter is constructed with a push-pull structure.

11. The output driving circuit of claim 8, wherein said inverter includes:
a PMOS transistor connected to an NMOS transistor, source of said PMOS transistor connected to said power supply, drain of said PMOS transistor connected to drain of said NMOS transistor, source of said NMOS transistor is grounded, and both gate of said PMOS transistor and gate of said NMOS transistor connected together as an input terminal of said control signal.
